(19) United States
(12) Patent Application Publication
(10) Pub. No.: US 2010/0176414 A1
(43) Pub. Date: Jul. 15, 2010

(54) PACKAGING STRUCTURE OF LIGHT-EMITTING COMPONENTS

(76) Inventor: I-LUNG CHUANG, KAOHSIUNG CITY (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/685,897

(22) Filed: Jan. 12, 2010

(30) Foreign Application Priority Data
Jan. 14, 2009 (CN) 200910005043.8

(51) Int. Cl. H01L 33/00

(52) U.S. Cl. 257/98; 257/E33.056; 257/E33.067

(57) ABSTRACT

The present invention provides a packaging structure of light-emitting components, comprising at least a light-emitting component, at least a connection wire, a base, at least a reflection surface, and an insulator, and characterized in that: the light-emitting component produces a light source and corresponding heat energy; the connection wire is coupled to the light-emitting component and at least an electrode; the electrode is disposed on the base; the light-emitting component is disposed on the base; the light-emitting component includes a heat-conducting base; the reflection surface reflects the light source produced by the light emitting component; the insulator insulates the electrode from the reflection surface; and the reflection surface is formed integrally with the heat-conducting base.

### FIELD OF THE INVENTION

The present invention relates generally to a packing structure, and particularly to a packaging structure of light-emitting components.

### BACKGROUND OF THE INVENTION

In comparison with conventional lighting sources, the lifetime of light-emitting diodes (LEDs) is 50 to 100 times longer while the power consumption thereof is only ⅓ to ⅕. In addition, LEDs have the advantages of high efficiency, low power consumption, fast response, low heat generation, and small volume, and thus conforming to the trend of miniaturization in various apparatuses. Thereby, LEDs are presently widely applied to circuits in varied fields and in different kinds of displays.

However, two aspects should be addressed while using LEDs. Firstly, while using LEDs as the light source, heat will be generated correspondingly. Whether the generated heat can be conducted away or dissipated from LEDs promptly will be the key factor determining the quality and lifetime of the LEDs, because the continuous rise in temperature of the LEDs due to the heat will possibly burn up the LEDs eventually. Beside, the second aspect is stressed on how to improve the brightness of the light generated by LEDs so that the LEDs can emit light with their greatest brightness. The two aspects described above have become the most important subjects in developing LEDs.

Accordingly, the LED structures according to the prior art have the drawbacks and problems mentioned above.

### SUMMARY

An objective of the present invention is to provide a packaging structure of light-emitting components, which can improve the brightness of the light emitted by the light-emitting component as well as dissipating the heat generated by the light-emitting component.

In order to achieve the objective described above, the present invention provides: a packaging structure of light-emitting components, comprising at least a light-emitting component, at least a connection wire, a base, at least a reflection surface, and an insulator, and characterized in that the light-emitting component produces a light source and corresponding heat energy; the connection wire is coupled to the light-emitting component and at least an electrode; the electrode is disposed on the base; the light-emitting component is disposed on the base; the light-emitting component includes a heat-conducting base, which conducts the heat energy produced by the light-emitting component; the reflection surface reflects the light source produced by the light emitting component; the insulator insulates the electrode from the reflection surface; and the reflection surface is formed integrally with the heat-conducting base.

The packaging structure of light-emitting components according to the present invention can be embodied using the following techniques. The base of the packaging structure has a chip-fixing region and a wiring region; the light-emitting component is disposed on the chip-fixing region; and the electrode is disposed on the wiring region. The reflection surface, the chip-fixing region, and the wiring region of the packaging structure are formed integrally. The reflection surface, the chip-fixing region, and the wiring region of the packaging structure are electroplated. The reflection surface, the chip-fixing region, and the wiring region of the packaging structure are silver electroplated. The base, the electrode, and the reflection surface of the packaging structure are formed integrally. The base, the electrode, and the reflection surface of the packaging structure are formed integrally by stamping and bending processes. The electrode of the base and the reflection surface of the packaging structure are formed by metals. The electrode of the base and the reflection surface of the packaging structure are electroplated. The electrode of the base and the reflection surface of the packaging structure are silver electroplated. The base and the reflection surface of the packaging structure are formed integrally. The base and the reflection surface of the packaging structure are formed by metals. The insulator of the packaging structure fixes the electrode of the base and the reflection surface. The insulator is formed by injection molding using polymer processing additives (PPAs). The light-emitting component of the packaging structure is a light-emitting diode.

The packaging structure of light-emitting components according to the present invention has the advantages of;

1. Improving brightness effectively;

2. Enhancing heat dissipation; and

3. Increasing lifetime of the light-emitting components.

### BRIEF DESCRIPTION OF THE DRAWINGS

FIG. 1 shows a schematic diagram of a packaging structure according to an embodiment of the present invention; and

FIG. 2 shows a sectional view of the packaging structure of FIG. 1 taken at the sectioning plane and in the direction indicated by the section line A-A′.

### DETAILED DESCRIPTION

In order to make the structure and characteristics as well as the effectiveness of the present invention to be further understood and recognized, the detailed description of the present invention is provided as follows along with embodiments and accompanying figures.

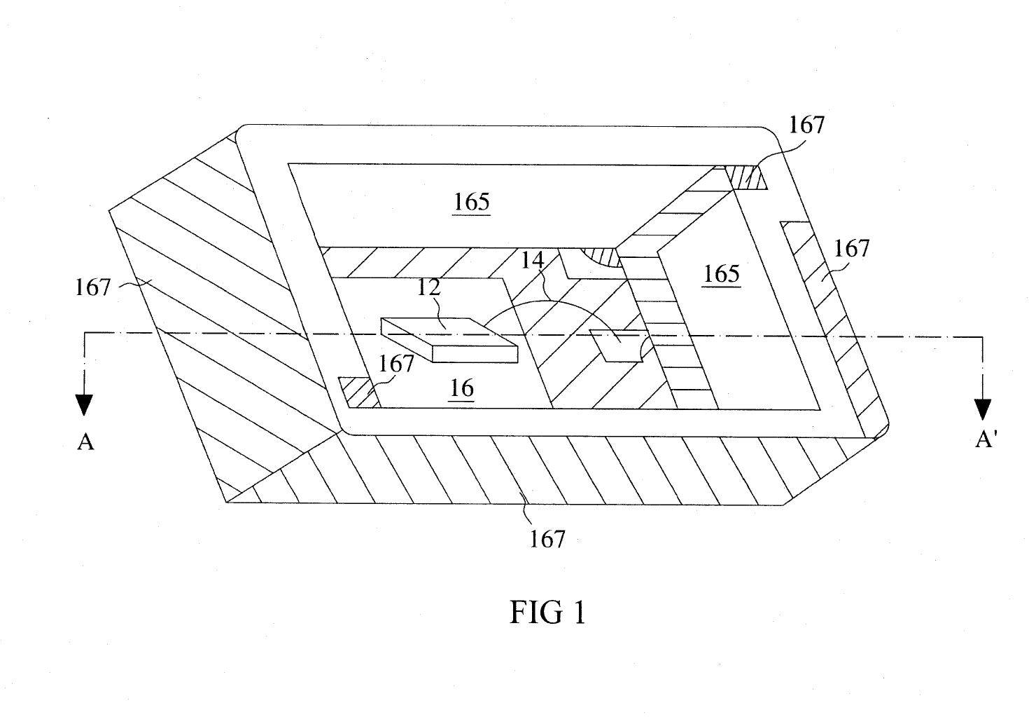

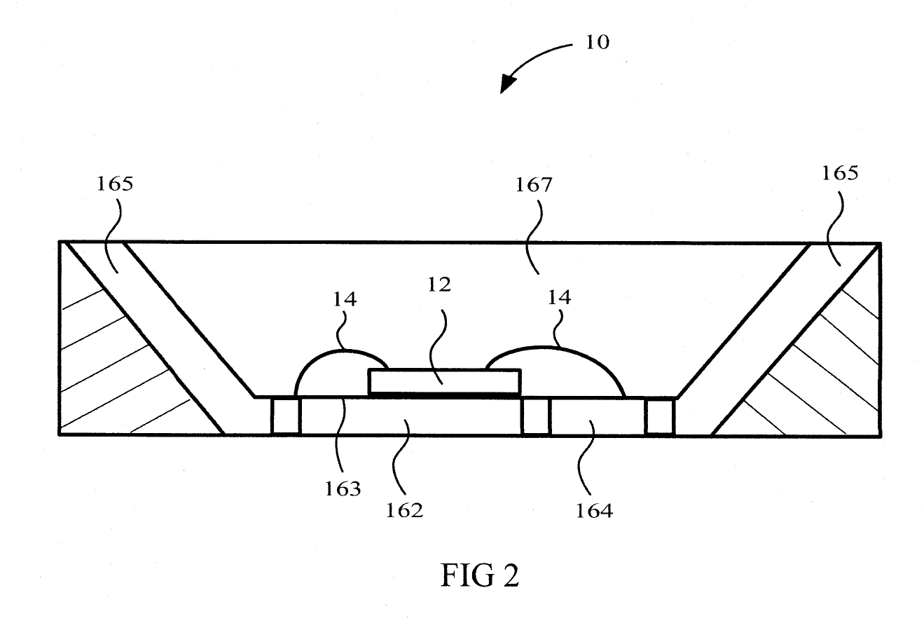

FIG. 1 shows a schematic diagram of a packaging structure according to an embodiment of the present invention; and FIG. 2 shows a sectional view of the packaging structure of FIG. 1 taken at the sectioning plane and in the direction indicated by the section line A-A′. As shown in the figures, the packaging structure of light-emitting components 10 comprises at least a light-emitting component 12, at least a connection wire 14, and a base 16. The light-emitting component 12 is used for producing a light source, which further corresponds to heat energy. According to an embodiment of the present invention, the light-emitting component 12 is a light-emitting diode. The connection wire 14 is used for coupling to the light-emitting component 12 and at least an electrode 161. Through the connection by the connection wire 14, the power needed by the light-emitting component 12 for producing the light source can be transmitted from the electrode 161 to the light-emitting component 12. The electrode 161 is disposed on the base 16, which is used for disposing the light-emitting component 12. The base 16 comprises a heat-conducting base 163, at least a reflection surface 165, and an insulator 167. The heat-conducting base 163 is used for conducting the heat energy generated by the light-emitting component. The reflection surface 165 is used for reflecting the light source produced by the light-emitting component 12. The insulator 167 is used for insulating the electrode 161 from the reflection surface 165. In addition, the reflection surface 165 is formed integrally with the heat-conducting base 163. In FIG. 1, the insulator 167 is filled with oblique lines.

The base includes a chip-fixing region 162 and a wiring region 164. The light-emitting component 12 is disposed on the chip-fixing region 162; and the electrode 161 is disposed on the wiring region 164. According to an embodiment of the present invention, the reflection surface 165, the chip-fixing region 162, and the wiring region 164 are formed integrally. Besides, the reflection surface 165, the chip-fixing region 162, and the wiring region 164 are formed by a special process. According to an embodiment of the present invention, the reflection surface 165, the chip-fixing region 162, and the wiring region 164 are formed by silver electroplating.

The electrode 161 of the base 161 is formed integrally with the reflection surface 165. According an embodiment of the present invention, the electrode 161 of the base 161 is formed integrally with the reflection surface 165 by stamping and bending processes. In addition, the electrode 161 of the base 161 and the reflection surface 165 are formed by metals. According to another embodiment of the present invention, the base 161 is formed integrally with the reflection surface 165. Besides, the base 161 and the reflection surface 165 are formed by the same metal.

The electrode 161 of the base 161 and the reflection surface 165 are formed by an electroplating process. According to another embodiment of the present invention, the electrode 161 and the reflection surface 165 are formed by silver electroplating.

The insulator 167 is used for fixing the electrode 161 of the base 16 and the reflection surface 165. According to an embodiment, the insulator 167 is formed by injection molding using polymer processing additives.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A packaging structure of light-emitting components, comprising at least a light-emitting component, at least a connection wire, a base, at least a reflection surface, and an insulator, and characterized in that:
said light-emitting component produces a light source and corresponding heat energy;
said connection wire is coupled to said light-emitting component and at least an electrode;
said electrode is disposed on said base;
said light-emitting component is disposed on said base;
said light-emitting component includes a heat-conducting base;
said reflection surface reflects said light source produced by said light emitting component;
said insulator insulates said electrode from said reflection surface; and
said reflection surface is formed integrally with said heat-conducting base.

2. The packaging structure of claim 1, and characterized in that said base has a chip-fixing region and a wiring region; said light-emitting component is disposed on said chip-fixing region; and said electrode is disposed on said wiring region.

3. The packaging structure of claim 1 or claim 2, and characterized in that said reflection surface, said chip-fixing region, and said wiring region are formed integrally.

4. The packaging structure of claim 3, and characterized in that said reflection surface, said chip-fixing region, and said wiring region are electroplated.

5. The packaging structure of claim 3, and characterized in that said reflection surface, said chip-fixing region, and said wiring region are silver electroplated.

6. The packaging structure of claim 1, and characterized in that said base, said electrode, and said reflection surface are formed integrally.

7. The packaging structure of claim 6, and characterized in that said base, said electrode, and said reflection surface are formed integrally by stamping and bending processes.

8. The packaging structure of claim 7, and characterized in that said electrode of said base and said reflection surface are metals.

9. The packaging structure of claim 8, and characterized in that said electrode of said base and said reflection surface are electroplated.

10. The packaging structure of claim 8, and characterized in that said electrode of said base and said reflection surface are silver electroplated.

11. The packaging structure of claim 1, and characterized in that said base and said reflection surface are formed integrally.

12. The packaging structure of claim 1, and characterized in that said base and said reflection surface are metals.

13. The packaging structure of claim 1, and characterized in that said insulator fixes said electrode of said base and said reflection surface.

14. The packaging structure of claim 1, and characterized in that said insulator is formed by injection molding using polymer processing additives.

15. The packaging structure of claim 1, and characterized in that said light-emitting component is a light-emitting diode.
